(19) United States
(12) Patent Application Publication
(10) Pub. No.: US 2026/0066238 A1
(43) Pub. Date: Mar. 5, 2026

(54) PLASMA PROCESSING APPARATUS AND ADAPTER

(71) Applicant: Kioxia Corporation, Tokyo (JP)

(72) Inventor: Shota ISHIKAWA, Yokkaichi Mie (JP)

(21) Appl. No.: 19/063,560

(22) Filed: Feb. 26, 2025

(30) Foreign Application Priority Data
Sep. 2, 2024 (JP) 2024-150939

(51) Int. Cl. H01J 37/32; H01L 21/67

(52) U.S. Cl. CPC H01J 37/32458; H01J 37/32568; H01J 2237/334

(57) ABSTRACT

According to one embodiment, a plasma processing system includes a processing container for processing a substrate, an upper electrode for supplying processing gas into the processing container, a lower electrode disposed in the processing container to face the upper electrode and on which the substrate is placed, and a power source for supplying power to at least one of the upper electrode and the lower electrode to generate plasma in the processing container, where the processing container includes an inclined surface that descends from an outer periphery side of the lower electrode toward a base of the lower electrode, and an exhaust port that is opened on the inclined surface and exhausts air from inside the processing container.

### CROSS-REFERENCE TO RELATED APPLICATION

This application is based upon and claims the benefit of priority from Japanese Patent Application No. 2024-150939, filed Sep. 2, 2024, the entire contents of which are incorporated herein by reference.

### FIELD

Embodiments described herein relate generally to a plasma processing apparatus and an adapter.

### BACKGROUND

In a manufacturing process of a semiconductor device, a plasma processing apparatus is used to process a substrate with plasma. Since a reaction product of plasma processing may adhere inside a processing container provided in the plasma processing apparatus, the processing container is subjected to dry cleaning at a predetermined cycle. However, depending on a shape of the processing container, it may be difficult to remove the adhering reaction product.

Examples of related art include JP-A-2021-532271, JP-A-2017-120830, and JP-A-2011-023563.

### DESCRIPTION OF THE DRAWINGS

FIGS. 1A to 1C are diagrams illustrating an example of a configuration of a plasma processing apparatus according to an embodiment;

FIGS. 2A and 2B are schematic diagrams illustrating plasma processing of a wafer by the plasma processing apparatus according to the embodiment;

FIGS. 3A and 3B are schematic diagrams illustrating a dry cleaning process of a chamber in the plasma processing apparatus according to the embodiment;

FIGS. 4AA to 4BB are schematic diagrams illustrating a dry cleaning process of a chamber in a plasma processing apparatus according to a comparative example;

FIGS. 5A to 5C are diagrams illustrating an example of a configuration of a plasma processing apparatus according to a first modification example of the embodiment;

FIGS. 6A and 6B are diagrams illustrating an example of a configuration of a plasma processing apparatus according to a second modification example of the embodiment;

FIGS. 7A and 7B are schematic diagrams illustrating a detailed configuration of an adapter according to the second modification example of the embodiment; and

FIGS. 8A and 8B are schematic top views illustrating a configuration of an adapter according to a third modification example of the embodiment.

### DETAILED DESCRIPTION

Embodiments provide a plasma processing apparatus and an adapter that allow a reaction product to be easily removed by dry cleaning.

In general, according to one embodiment, a plasma processing apparatus includes a processing container for processing a substrate, an upper electrode for supplying processing gas into the processing container, a lower electrode disposed in the processing container to face the upper electrode and on which the substrate is placed, and a power source for supplying power to at least one of the upper electrode and the lower electrode to generate plasma in the processing container, where the processing container includes an inclined surface that descends from an outer periphery side of the lower electrode toward a base of the lower electrode, and an exhaust port that is opened on the inclined surface and exhausts air from inside the processing container.

Hereinafter, embodiments of the present disclosure will be described in detail with reference to the drawings. The present disclosure is not limited to the following embodiments. Components in the following embodiments include those that can be easily imagined by a person skilled in the art or those that are substantially the same.

### Configuration Example of Plasma Processing Apparatus

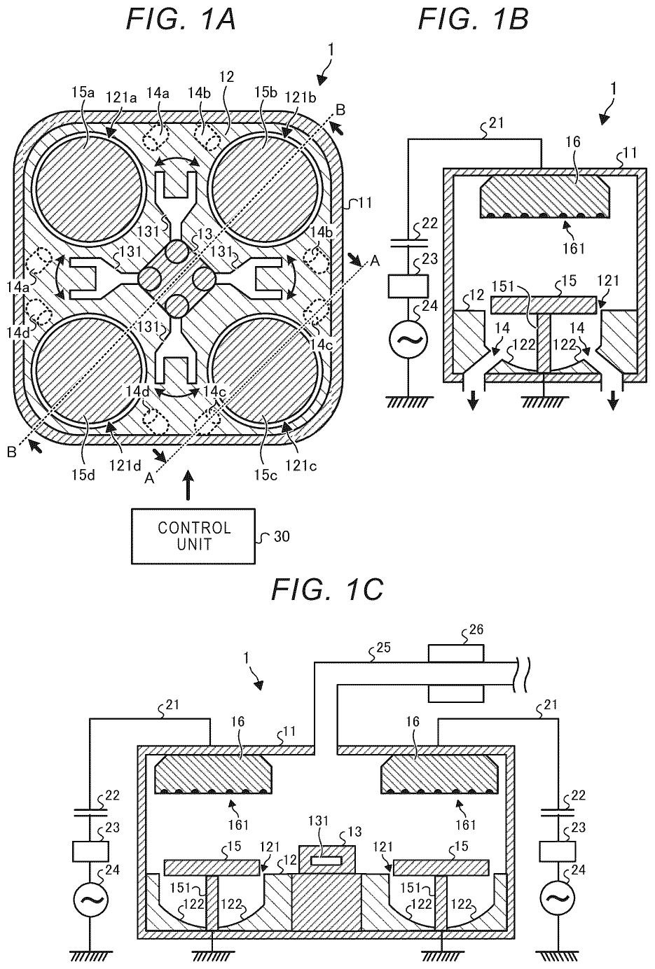

FIGS. 1A to 1C are diagrams illustrating an example of a configuration of a plasma processing apparatus 1 according to the embodiment. More specifically, FIG. 1A is a top view of inside of a chamber 11 provided in the plasma processing apparatus 1. FIG. 1B is a cross-sectional view taken along a line A-A in FIG. 1A. FIG. 1C is a cross-sectional view taken along a line B-B in FIG. 1A.

The plasma processing apparatus 1 illustrated in FIGS. 1A to 1C is configured as a plasma-enhanced chemical vapor deposition (PECVD) apparatus for forming a predetermined film on, for example, a wafer.

As illustrated in FIGS. 1A to 1C, the plasma processing apparatus 1 includes the chamber 11 (also referred to herein as “chamber system 11” and/or “processing container 11”) as a processing container for processing a wafer. The chamber 11 (e.g., processing container) includes a rectangular shape, is made of, for example, aluminum including an aluminum oxide coating, and can be airtightly sealed. Each part of the chamber 11 such as a side wall and a top plate is configured to be adjustable to a predetermined temperature by a heater or the like (not illustrated).

A discharge tube 25 is connected to the top plate of the chamber 11. Another end of the discharge tube 25 is connected to a gas supply source (not illustrated), and a microwave generation source 26 is provided to the discharge tube 25 between the chamber 11 and the gas supply source.

A plurality of pairs of shower heads 16 and electrostatic chucks 15, that are upper and lower electrodes, are provided in the chamber 11. The shower head 16 and the electrostatic chuck 15 are disposed in point symmetry with respect to a center of the chamber 11 when viewed from above.

In the example of FIGS. 1A to 1C, four pairs of shower heads 16 and electrostatic chucks 15 are provided in the chamber 11. The electrostatic chucks 15a to 15d and the corresponding shower heads 16 are disposed, for example, near four corners of the chamber 11 including a rectangular shape to surround the center of the chamber 11.

However, the number of pairs of shower heads 16 (e.g., upper electrodes) and electrostatic chucks 15 (e.g., lower electrodes) disposed in the chamber 11 is not limited to four. The number of pairs of shower heads 16 and electrostatic chucks 15 in the chamber 11 may be three or less, or may be five or more. The pair of the shower head 16 and the electrostatic chuck 15 disposed in the chamber 11 do not have to be plural, and only one pair of the shower head 16 and the electrostatic chuck 15 may be disposed.

Each of the shower heads 16 functioning as upper electrodes is provided at a top of the chamber 11. The upper electrodes can generally be referred to as conductive components positioned above the substrate that receive electrical power and facilitate plasma generation by acting as an active electrode. Each of the shower heads 16 is connected to a gas supply pipe (not illustrated) that is connected to the gas supply source, and supplies processing gas used to process the wafer into the chamber 11. A plurality of gas supply ports 161 are provided on lower surfaces of the shower heads 16, and processing gas is supplied into the chamber 11 from the gas supply ports.

A power supply line 21 is connected to the shower heads 16 serving as upper electrodes. A blocking capacitor 22, a matching unit 23 (also referred to herein as “matching system 23”), and a high frequency power supply 24 are connected to the power supply line 21.

Each of the electrostatic chucks 15 is disposed below the corresponding shower head 16 to face (e.g., be arranged in an opposing configuration such that an electric field can be established between them) the corresponding shower head 16.

Each of the electrostatic chucks 15 functions as a lower electrode. The lower electrodes can generally be referred to as conductive components positioned below the substrate that provide a reference potential or counter-electrode. A lower electrode can be disposed in the processing container (e.g., chamber 11) to face the upper electrode and configured to support the substrate (e.g., wafer). The electrostatic chucks 15 horizontally support a wafer to be processed within the chamber 11 and include a chuck mechanism (not illustrated) that electrostatically adsorbs to the wafer. A surface of the electrostatic chuck 15 on which the wafer is placed can be adjusted to a predetermined temperature by a heater or the like (not illustrated).

A transfer opening for wafer (not illustrated) is provided on a side surface of the chamber 11, and the wafer is placed on the electrostatic chucks 15 in the chamber 11 from the transfer opening by a transfer robot (not illustrated).

More specifically, a spindle 13 is disposed in the center of the chamber 11 when viewed from above. The spindle 13 includes, for example, the same number of transfer arms 131 as the number of electrostatic chucks 15 disposed in the chamber 11. The transfer arms 131 are configured to be rotatable in a circumferential direction by the spindle 13, and are usually positioned between each of the electrostatic chucks 15, that are standby positions for the transfer arms 131.

The spindle 13 rotates the transfer arms 131, allowing the transfer arms 131 to transfer wafers between transfer robots outside the chamber 11 and each of the electrostatic chucks 15.

A base 151 of the electrostatic chuck 15 is connected to a bottom wall of the chamber 11, thereby supporting the electrostatic chuck 15 near a vertical center of the chamber 11 a predetermined distance away from the shower head 16 to face (e.g., be positioned in opposing alignment with, such that a potential difference can be established between them to facilitate plasma generation) to the shower head 16 in parallel.

According to such structure, the pair of the shower head 16 and the electrostatic chuck 15 forms a pair of parallel plate electrodes. During plasma processing, processing gas is supplied into the chamber 11 from the shower head 16, while high frequency power of predetermined frequency is applied to the shower head 16 from the high frequency power source 24 connected to the shower head 16. According to such mechanism, plasma of the processing gas is generated in the chamber 11.

In the plasma processing apparatus 1 of the embodiment configured as a PECVD apparatus, for example, a predetermined film is formed on the wafer by the plasma of the processing gas. By such plasma processing, a reaction product of the same type as the predetermined film on the wafer is deposited in the chamber 11.

Therefore, in the plasma processing apparatus 1, dry cleaning is performed every time a predetermined number of plasma processing are performed on wafers, and depositions accumulated in the chamber 11 are removed. In dry cleaning, instead of a method in which high frequency power is supplied from the high frequency power supply 24 to generate plasma between the parallel plate electrodes of the shower head 16 and the electrostatic chuck 15, plasma generated by the microwave generation source 26 described above is used.

That is, cleaning gas introduced from the gas supply source into the discharge tube 25 is converted into plasma by the microwave generation source 26 and introduced into the chamber 11. Such plasma is also called remote plasma, and dry cleaning using remote plasma is also called remote plasma cleaning (RPC).

Dry cleaning using remote plasma allows gentle plasma processing with less ion bombardment or the like compared to plasma directly generated in the chamber 11 using the parallel plate electrodes or the like, and can prevent damage caused by plasma to components in the chamber 11. Accordingly, it is possible to extend a lifespan of the components in the chamber 11.

A lower member 12 is disposed around an outer periphery of the electrostatic chuck 15 below the chamber 11. The lower member 12 includes a plurality of recess portions 121 (121a to 121d), and the above-described electrostatic chucks 15a to 15d are disposed to correspond to each of the recess portions 121a to 121d. According to such configuration, bottom surfaces of the recess portions 121 in the lower member 12 substantially correspond to the bottom wall of the chamber 11.

The bottom surface of each of the recess portions 121, that is, a bottom wall portion of the chamber 11, forms an inclined surface 122 that descends from an outer periphery side of the electrostatic chuck 15 to the base 151. That is, the inclined surfaces 122 are configured in an annular shape surrounding the electrostatic chucks 15 at positions slightly below each of the electrostatic chucks 15. Therefore, the inclined surfaces 122 have a curved surface shape in a circumferential direction. As illustrated in FIGS. 1B and 1C, the inclined surfaces 122 may have a curved surface shape convex downward in an inclination direction, or may have a flat shape.

A pair of exhaust ports 14 are formed in each of the inclined surfaces 122. The exhaust ports 14 are provided in pairs corresponding to each of the electrostatic chucks 15, penetrate the bottom wall of the chamber 11, and are connected to a vacuum pump (not illustrated).

A pair of exhaust ports 14 corresponding to each of the electrostatic chucks 15 are provided on both sides of the corresponding electrostatic chuck 15 such that a corner portion (e.g., a junction where two walls or boundaries of the chamber 11 meet) of the chamber 11 where the corresponding electrostatic chuck 15 is disposed is interposed therebetween (e.g., positioned between the two inclined surfaces in a manner that spatially separates them while maintaining their opposing alignment). As a result, the pair of exhaust ports 14 are disposed at positions facing each other with the corresponding electrostatic chuck 15 interposed therebetween.

That is, a pair of exhaust ports 14a are arranged corresponding to the electrostatic chuck 15a with the electrostatic chuck 15a interposed therebetween, and a pair of exhaust ports 14b are arranged corresponding to the electrostatic chuck 15b with the electrostatic chuck 15b interposed therebetween. A pair of exhaust ports 14c are arranged corresponding to the electrostatic chuck 15c with the electrostatic chuck 15c interposed therebetween, and a pair of exhaust ports 14d are arranged corresponding to the electrostatic chuck 15d with the electrostatic chuck 15d interposed therebetween.

As a result, one exhaust port 14a of the pair of exhaust ports 14a corresponding to the electrostatic chuck 15a is adjacent to one exhaust port 14b of the pair of exhaust ports 14b corresponding to the electrostatic chuck 15b, and the other exhaust port 14a is adjacent to one exhaust port 14d of the pair of exhaust ports 14d corresponding to the electrostatic chuck 15d.

The other exhaust port 14b corresponding to the electrostatic chuck 15b is adjacent to one exhaust port 14c of the pair of exhaust ports 14c corresponding to the electrostatic chuck 15c. The other exhaust port 14c corresponding to the electrostatic chuck 15c is adjacent to the other exhaust port 14d corresponding to the electrostatic chuck 15d.

According to the above-described configuration, an atmosphere in the chamber 11 (e.g., processing container) such as the processing gas supplied to the electrostatic chuck 15, decomposition products of the processing gas, and reaction products is exhausted via the exhaust ports 14.

The plasma processing apparatus 1 includes a control unit 30 (also referred to herein as “control system 30”) that controls each unit of the plasma processing apparatus 1 such as the high frequency power supply 24, the matching unit 23, the microwave generation source 26, the spindle 13, a vacuum pump (not illustrated), and a chuck mechanism (not illustrated).

The control unit 30 is configured as a computer including, for example, a central processing unit (CPU) (also referred to herein as “processor(s),” “processing circuits,” and/or “processing systems”), a read only memory (ROM), a random access memory (RAM), and the like. However, the control unit 30 may be configured as an application specific integrated circuit (ASIC) or the like including functions to be used as the plasma processing apparatus 1 (also referred to herein as “plasma processing system 1”).

During plasma processing, a wafer to be processed is placed on the electrostatic chuck 15 and adsorbed by the chuck mechanism under control of the control unit 30. The inside of the chamber 11 is evacuated by the vacuum pump connected to the exhaust port 14. When a pressure inside the chamber 11 reaches a predetermined pressure, the processing gas is supplied from the gas supply source (not illustrated) to the shower head 16 and then supplied into the chamber 11 via the gas supply port 161.

Under control of the control unit 30, high frequency voltage is applied to the shower head 16 that is the upper electrode, while the electrostatic chuck 15 that is the lower electrode is grounded, to generate plasma in the chamber 11. In the plasma, the processing gas, decomposition products of the processing gas, and the like undergo chemical and physical reactions, and reaction products are deposited on the wafer, forming a predetermined film on the wafer.

### Example of Plasma Processing

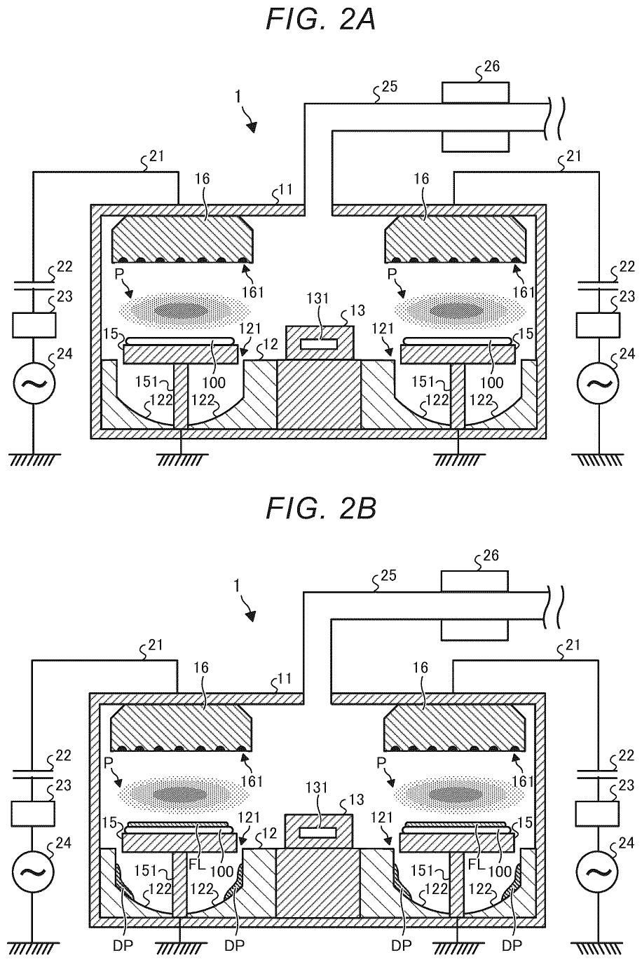

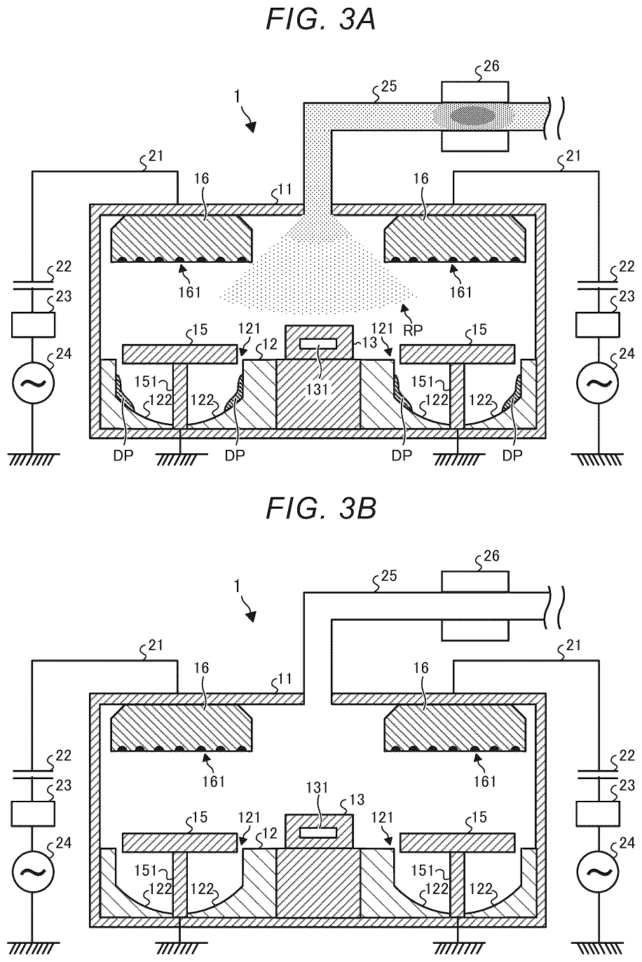

Next, an example of plasma processing of a wafer 100 and dry cleaning of the chamber 11 by the plasma processing apparatus 1 of the embodiment will be described with reference to FIGS. 2A to 3B.

FIGS. 2A and 2B are schematic diagrams for illustrating plasma processing of the wafer 100 by the plasma processing apparatus 1 according to the embodiment.

As illustrated in FIG. 2A, the control unit 30 uses the transfer robot (not illustrated) to load wafers 100 as a plurality of substrates into the chamber 11, and uses each of the transport arms 131 of the spindle 13 to place and chuck the wafers 100 on each of the plurality of electrostatic chucks 15. The plurality of substrates wafers 100 formed from semiconductor material and configured for plasma processing. The control unit 30 supplies processing gas into the chamber 11 while applying high frequency voltage to the shower head 16 using the high h frequency power supply 24 to generate plasma P of the processing gas between the shower head 16 and the electrostatic chuck 15 corresponding to each other.

In the plasma processing apparatus 1 of the embodiment, for example, source gas for a CVD carbon film is supplied as the processing gas. The CVD carbon film is a film of which a main component is carbon.

As illustrated in FIG. 2B, by the above-described plasma processing, a predetermined film, for example a CVD carbon film FL, is formed on each of the wafers 100. By performing such plasma processing a predetermined number of times, a deposition DP including the same components as the CVD carbon film FL is deposited on various members in the chamber 11 such as the recess portion 121 of the lower member 12.

FIGS. 3A and 3B are schematic diagrams for illustrating the dry cleaning process of the chamber 11 (e.g., processing container) in the plasma processing apparatus 1 according to the embodiment. As described above, the dry cleaning process is performed every time the plasma processing is performed a predetermined number of times. A frequency of the dry cleaning process may be, for example, every time the plasma processing is performed, or every time the plasma processing is repeated several times.

As illustrated in FIG. 3A, the control unit 30 causes the microwave generation source 26 to convert cleaning gas in the discharge tube 25 into plasma, and introduces the plasma into the chamber 11 as remote plasma RP. As described above, when the predetermined film formed on the wafer 100 is the CVD carbon film FL and the deposition DP is the same type of carbon-based reaction product, the cleaning gas may be, for example, oxygen gas.

During the dry cleaning process, a dummy wafer may be placed on each of the electrostatic chucks 15 on which the wafer 100 is placed to protect the surface of the electrostatic chucks 15.

As illustrated in FIG. 3B, the deposition DP adhering to various members in the chamber 11 such as the recess portion 121 of the lower member 12 is removed by the remote plasma RP of oxygen gas.

Here, the atmosphere inside the chamber 11 flows toward the exhaust ports 14 provided near the side walls on the four sides of the rectangular chamber 11. Therefore, in the recess portions 121 of the lower member 12, the remote plasma RP of oxygen gas is less likely to reach the sides closer to the four corners of the chamber 11 than the other portions.

However, in the plasma processing apparatus 1 of the embodiment, the bottom surface of each of the recess portions 121 is the inclined surface 122, so that the remote plasma RP of oxygen gas can be sufficiently distributed, and the depositions DP can be prevented from remaining on the annular inclined surfaces 122 of the recess portions 121 near the four corner portions of the chamber 11.

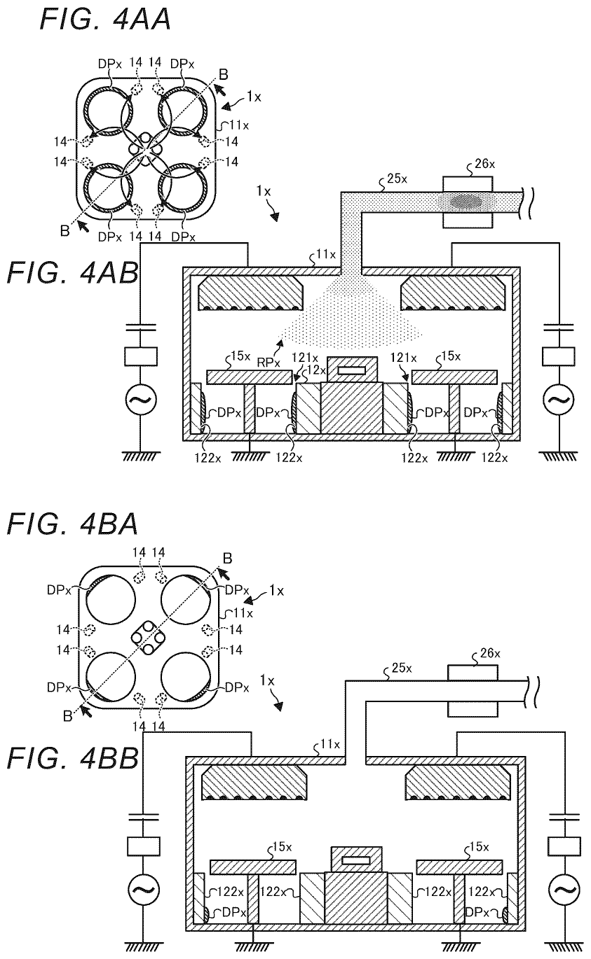

Comparative Example: Next, an example of dry cleaning in a plasma processing apparatus 1x of comparative example will be described with reference to FIGS. 4AA to 4BB. FIGS. 4AA to 4BB are schematic diagrams illustrating a dry cleaning process of a chamber 11x (e.g., processing container) in the plasma processing apparatus 1x according to the comparative example.

As illustrated in a cross-sectional view of FIG. 4AB, the plasma processing apparatus 1x of the comparative example includes a lower member 12x in the chamber 11x. The lower member 12x includes a plurality of recess portions 121x in which each of electrostatic chucks 15x are respectively disposed. In the plasma processing apparatus 1x of the comparative example, each of the plurality of recess portions 121x includes a side surface 122x perpendicular to the bottom wall of the chamber 11x.

Also in the plasma processing apparatus 1x of the comparative example, by performing plasma processing a predetermined number of times, deposition DPx is accumulated on each member in the chamber 11x including the side surface 122x in the recess portion 121x of the lower member 12x.

Here, for example, cleaning gas in a discharge tube 25x is turned into plasma by a microwave generation source 26x, and the plasma is introduced into the chamber 11x as remote plasma RPx, thereby performing dry cleaning in the chamber 11x.

Here, as illustrated in a top view of FIG. 4AA, the cleaning gas introduced from a center of the chamber 11x when viewed from above flows toward the exhaust ports 14 provided near side walls on four sides of the chamber 11x. Therefore, it is difficult for the cleaning gas and the remote plasma RPx of the cleaning gas to reach the four corners of the chamber 11x.

The side surface 122x of the recess portion 121x of the lower member 12x, and the like are in a relatively low temperature state compared to parts that are heated to a predetermined temperature such as the side walls and a top plate of the chamber 11x and a mounting surface of the electrostatic chuck 15x.

As illustrated in FIGS. 4BA and 4BB, due to the configuration described above, the deposition DPx may not be completely removed from the side surface 122x of the recess portion 121x of the lower member 12x and may remain on sides closer to the corner portions of the chamber 11x.

As such, areas in the chamber 11x where the cleaning gas or the like cannot easily reach and areas in the chamber 11x that have relatively low temperature are also called dead spots and cold spots, respectively, and are considered to be areas where it is difficult to remove the deposition DPx by dry cleaning. As described above, when the deposition DPx remains in the chamber 11x, in the subsequent plasma processing, a rate at which a predetermined film is formed on the wafer varies, and in-plane uniformity of a thickness of the predetermined film deteriorates. The remaining deposition DPx may clog various pipes such as exhaust ports.

Therefore, to remove the deposition DPx on the side surface 122x of the recess portion 121x of the lower member 12x, a method can be considered that combines conditions under which the deposition DPx on the corner portions of the chamber 11x is easily removed and conditions under which the deposition DPx on other portions is easily removed. However, combination of a plurality of conditions requires a long time for dry cleaning, which results in a long downtime of the plasma processing apparatus 1x.

Alternatively, a method may be considered in which corrosive gas such as NF₃ gas is added to cleaning gas such as oxygen gas to improve a removal rate of the deposition DPx. However, when corrosive gas is used for dry cleaning, various components of the chamber 11x are likely to be damaged, resulting in a shortened lifespan.

According to the plasma processing apparatus 1 of the embodiment, the chamber 11 includes the inclined surface 122 that descends from the outer periphery side of the electrostatic chuck 15 toward the base 151 (e.g., in the direction of) of the electrostatic chuck 15. Accordingly, dead spots in the recess portions 121 of the lower member 12 are eliminated, making it easier to expose the dead spots to the remote plasma RP of the cleaning gas.

Therefore, the deposition DP can be easily removed by dry cleaning. Dry cleaning can be completed in a short time and an operating rate of the plasma processing apparatus 1 can be improved. It is also possible to extend lifespan of the members in the chamber 11.

In the above-described embodiment, the plasma processing apparatus 1 includes the inclined surface 122 including an annular shape in the recess portion 121 of the lower member 12. However, in each of the recess portions 121, the deposition DP on the central side of the chamber 11 when viewed from above is relatively easy to remove. Therefore, the inclined surface 122 may be provided only on the corner portion sides of the chamber 11 where it is difficult to remove the deposition DP.

### First Modification Example

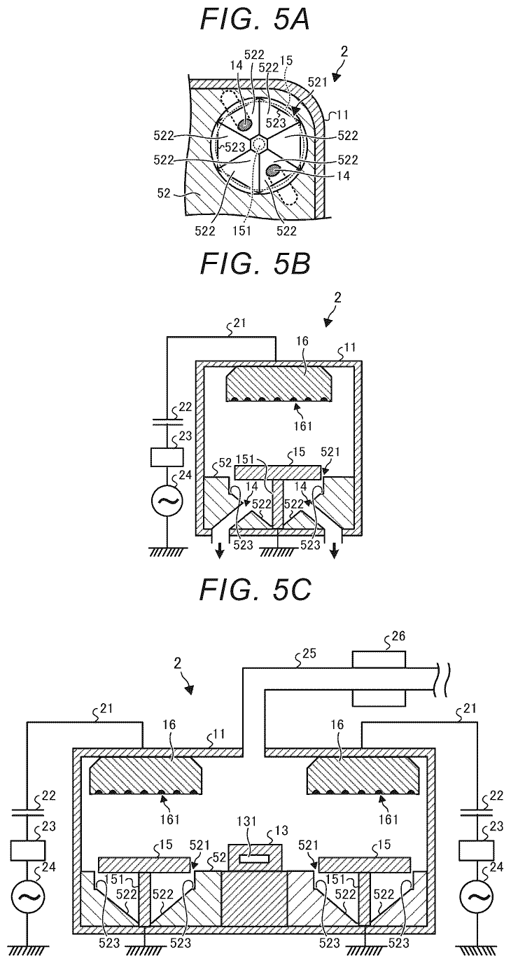

Next, a plasma processing apparatus 2 according to a first modification example of the embodiment will be described with reference to FIGS. 5A to 5C. In the plasma processing apparatus 2 of the first modification example, a shape of an inclined surface 522 of a lower member 52 is different from that of the above-described embodiment.

FIGS. 5A to 5C are diagrams illustrating an example of a configuration of the plasma processing apparatus 2 according to the first modification example of the embodiment.

More specifically, FIG. 5A is an enlarged top view of a portion in the chamber 11 (e.g., processing container) provided in the plasma processing apparatus 2. In FIG. 5A, the electrostatic chuck 15 and the base 151 thereof are indicated by dashed lines, and the lower structure is illustrated through the dashed line portions. FIG. 5B is a cross-sectional view corresponding to the cross-section of FIG. 1B described above. FIG. 5C is a cross-sectional view corresponding to the cross-section of FIG. 1C described above.

In FIGS. 5A to 5C, the similar components as those in the above-described embodiment are denoted by the same reference numerals, and the description thereof may be omitted.

As illustrated in FIGS. 5A to 5C, the plasma processing apparatus 2 of the first modification example includes the lower member 52 in the chamber 11 (e.g., processing container). The lower member 52 includes a plurality of recess portions 521 in which the plurality of electrostatic chucks 15 are respectively disposed. The bottom of each of the recess portions 521 includes a plurality of inclined surfaces 522 that descend from the outer periphery side of the electrostatic chuck 15 toward the base 151 of the electrostatic chuck 15.

The inclined surfaces 522 include a plurality of flat surfaces arranged to surround the base 151 of the electrostatic chuck 15. That is, compared to the inclined surfaces 122 of the above-described embodiment that have a curved surface shape convex downward in the inclination direction (e.g., sloping downward from an outer periphery toward a lower central region, forming a continuous or gradual transition) and/or a curved surface shape in the circumferential direction (e.g., following a non-linear profile around the base 151 in a manner that forms a continuous arc or contour), the inclined surfaces 522 have a flat surface shape in both the inclination direction and the circumferential direction.

In the example of FIGS. 5A to 5C, each of the recess portions 521 includes six inclined surfaces 522 surrounding the base 151 of the electrostatic chuck 15. As a result, each of upper ends of the six inclined surfaces 522 that form a regular hexagon when viewed from above are connected to vertical wall surfaces of the recess portion 521 of the lower member 52. A step 523 may be formed in a part of a connecting portion between the inclined surface 522 and the vertical wall surface of the recess portion 521.

Among the six inclined surfaces 522 surrounding the base 151 of the electrostatic chuck 15, two inclined surfaces 522 that face each other with a corner portion of the chamber 11 interposed therebetween are provided with the exhaust port 14, respectively.

When the inclined surface 522 in the recess portion 521 is configured by combining a plurality of flat surfaces, the number of inclined surfaces 522 in one recess portion 521 is not limited to six. The number of inclined surfaces 522 in one recess portion 521 may be five or less, or seven or more.

According to the plasma processing apparatus 2 of the first modification example, the inclined surface 522 includes a plurality of flat surfaces arranged to surround the base 151 of the electrostatic chuck 15. Also in such configuration, the same effects as those of the plasma processing apparatus 1 of the above-described embodiment can be achieved.

In the above-described first modification example, the inclined surface 522 includes a plurality of flat surfaces arranged to surround the base 151 of the electrostatic chuck 15. However, the inclined surface 522 including one or more flat surfaces may be provided only on the corner portion sides of the chamber 11 of the recess portion 521 including a circular shape where it is difficult to remove the deposition DP.

### Second Modification Example

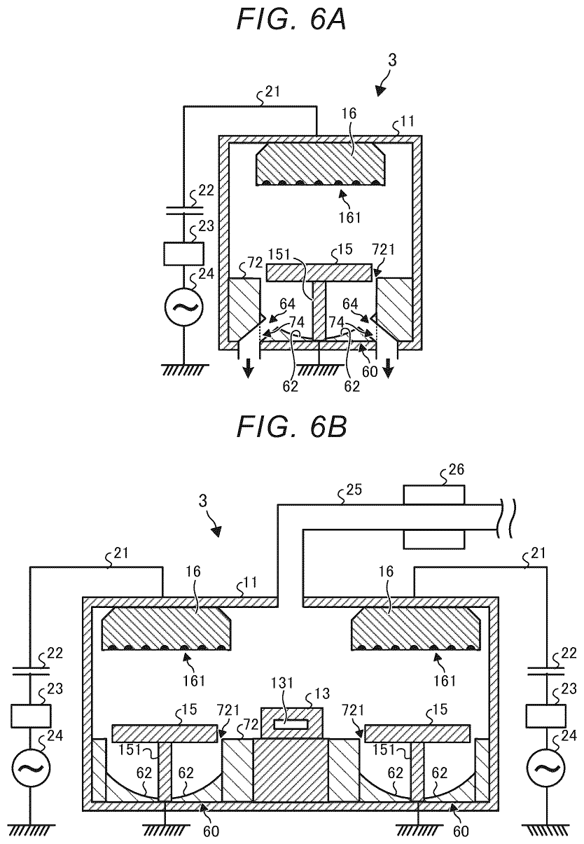

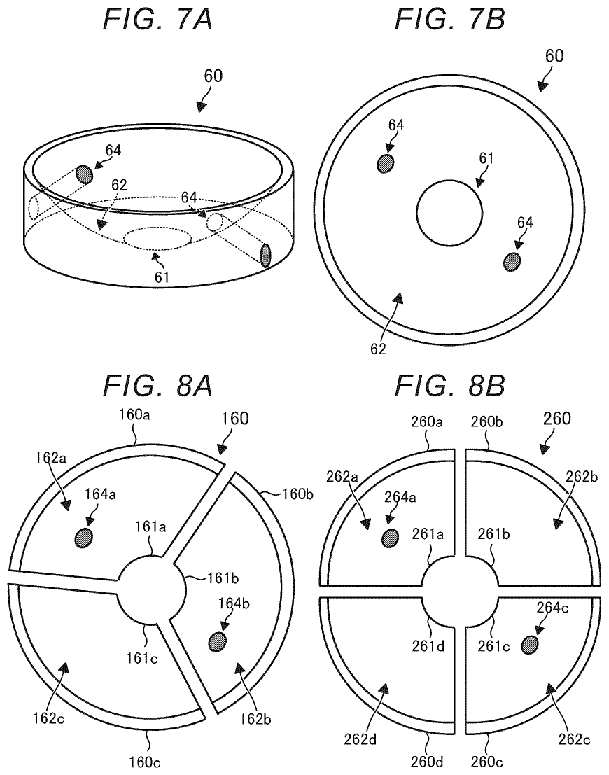

Next, a plasma processing apparatus 3 according to a second modification example of the embodiment will be described with reference to FIGS. 6A to 7B. The plasma processing apparatus 3 of the second modification example is different from the above-described embodiment in that an adapter 60 including an inclined surface 62 is provided.

In the following drawings, the similar components as those in the above-described embodiment are denoted by the same reference numerals, and the description thereof may be omitted.

FIGS. 6A and 6B are diagrams illustrating an example of a configuration of the plasma processing apparatus 3 according to the second modification example of the embodiment. More specifically, FIG. 6A is a cross-sectional view corresponding to the cross-section of FIG. 1B described above, and FIG. 6B is a cross-sectional view corresponding to the cross-section of FIG. 1C described above.

As illustrated in FIGS. 6A and 6B, the plasma processing apparatus 3 of the second modification example includes a lower member 72 including a plurality of recess portions 721 in which a plurality of electrostatic chucks 15 are respectively disposed. Each of the recess portions 721 includes a vertical wall surface, and an exhaust port 74 connected to a vacuum pump (not illustrated) is provided on each of the vertical walls. The adapter 60 including the inclined surface 62 is disposed at the bottom of each of the recess portions 721.

The adapter 60 preferably includes the same material as the components of chamber 11, for example, aluminum including an aluminum oxide coating. However, the adapter 60 may be made of a material different from that of the chamber 11 such as resin. The adapter 60 and the inclined surface 62 of the adapter 60 have an annular shape that matches the shape of the recess portion 721 of the lower member 72.

That is, the inclined surface 62 of the adapter 60 includes a curved surface shape in the circumferential direction. The inclined surface 62 includes a curved surface shape convex downward in the inclination direction. However, the inclined surface 62 may have a flat surface shape in the inclined direction. Exhaust ports 64 are opened in the inclined surfaces 62 and connected to the exhaust ports 74 of the lower member 72.

FIGS. 7A and 7B are schematic diagrams illustrating a detailed configuration of the adapter 60 according to the second modification example of the embodiment. More specifically, FIG. 7A is a transparent perspective view of the adapter 60, and FIG. 7B is a top view of the adapter 60.

As illustrated in FIGS. 7A and 7B, the adapter 60 includes a cylindrical outer shape that matches the shape of the recess portion 721 of the lower member 72 as described above. An opening 61 is provided at a bottom of the adapter 60 through which the base 151 of the electrostatic chuck 15 passes. The inclined surface 62 of the adapter 60 descends from a side wall portion of the adapter 60 including a cylindrical shape toward the opening 61 at the bottom of the adapter 60.

As described above, the inclined surface 62 includes a curved surface shape convex downward in the inclination direction or a flat surface shape, and includes a curved surface shape in the circumferential direction. The inclined surface 62 is provided with the pair of exhaust ports 64 corresponding to the pair of exhaust ports 74 provided in the recess portion 721 of the lower member 72 (e.g., exhaust ports 64 positioned on the inclined surface 62 and operatively aligned with exhaust ports 74, which are formed on the lower member 72). The pair of exhaust ports 64 are provided at positions facing each other with the opening 61 of the adapter 60 interposed therebetween.

As a result, when the adapter 60 is installed in the chamber 11 of the plasma processing device 3, the pair of exhaust ports 64 face each other with the electrostatic chuck 15 interposed therebetween and are connected to the exhaust ports 74 provided in the lower member 72.

According to the plasma processing apparatus 3 of the second modification example, the inclined surface 62 is provided on the adapter 60 attached (e.g., attachable) to the lower part of the chamber 11. As such, by preparing the adapter 60 with the inclined surface 62 separately from the chamber 11, even in the plasma processing device 3 in which the side wall in the recess portion 721 of the lower member 72 includes a vertical shape, by attaching the adapter 60, the deposition DP can be easily removed by dry cleaning.

According to the plasma processing apparatus 3 of the second modification example, the inclined surface 62 includes the exhaust port 64 opened therein, in which the exhaust port 64 is connected to the exhaust port 74 of the lower member 72. Accordingly, the atmosphere inside the chamber 11 can be exhausted through the adapter 60.

The plasma processing apparatus 3 of the second modification example provides the same effects as the plasma processing apparatus 1 of the above-described embodiment.

The inclined surface 62 of the adapter 60 of the second modification example includes a shape similar to that of the inclined surface 122 of the plasma processing apparatus 1 of the embodiment, for example. However, the shape of the inclined surface 62 of the adapter 60 is not limited thereto. As an example, the inclined surface 62 may have a shape in which a plurality of flat surfaces are combined, similar to the first modification example described above.

### Third Modification Example

Next, adapters 160 and 260 according to a third modification example of the embodiment will be described with reference to FIGS. 8A and 8B. The adapters 160 and 260 of the third modification example are different from that of the second modification described above in that the adapters 160 and 260 are configured to be separable.

FIGS. 8A 8B are and schematic top views illustrating a configuration of the adapters 160 and 260 according to the third modification example of the embodiment. In FIGS. 8A and 8B, the similar components as those in the above-described second modification example are denoted by the same reference numerals, and the description thereof may be omitted.

As illustrated in FIG. 8A, as an example, the adapter 160 according to the third modification example includes a combination of three separable members 160a to 160c. Each of the members 160a to 160c includes a pie shape. The members 160a to 160c respectively include arcuate portions 161a to 161c with an angle range of 120° at a position that becomes a center of the whole combined members. As a result, when the members 160a to 160c are combined with each other, the members 160a to 160c have a cylindrical outer shape and include an opening in the center through which the base 151 of the electrostatic chuck 15 can pass similar to the adapter 60 of the above-described second modification example.

The members 160a to 160c respectively include inclined surfaces 162a to 162c that descend from an outer periphery toward the respective arcuate portions 161a to 161c. The inclined surfaces 162a to 162c each have a curved surface shape convex downward in the inclination direction or a flat surface shape, and have a curved surface shape in the circumferential direction. However, each of the inclined surfaces 162a to 162c may include one or more flat surfaces, similar to the inclined surface 522 of the above-described first modification example.

Among the inclined surfaces 162a to 162c, the inclined surfaces 162a and 162b are provided with exhaust ports 164a and 164b at positions facing each other with the arcuate portions 161a and 161b interposed therebetween. Accordingly, when the adapter 160 in which the members 160a to 160c are combined is attached inside the chamber 11, the exhaust ports 164a and 164b are connected to the exhaust ports 74 of the lower member 72.

As illustrated in FIG. 8B, as another example, the adapter 260 according to the third modification example is configured by combining four divided members 260a to 260d. Each of the members 260a to 260d includes a pie shape. The members 260a to 260d include arcuate portions 261a to 261d each including an angle of 90° at a position that becomes a center of the whole combined members. As a result, when the members 260a to 260d are combined with each other, the members 260a to 260d have a cylindrical outer shape and include an opening in the center through which the base 151 of the electrostatic chuck 15 can pass similar to the adapter 60 of the above-described second modification example.

Each of the members 260a to 260d include each of inclined surfaces 262a to 262d that descend from an outer periphery toward the respective arcuate portions 261a to 261d. The inclined surfaces 262a to 262d each have a curved surface shape convex downward in the inclination direction or a flat shape, and have a curved surface shape in the circumferential direction. However, each of the inclined surfaces 262a to 262d may include one or more flat surfaces, similar to the inclined surface 522 of the above-described first modification example.

Among the inclined surfaces 262a to 262d, the inclined surfaces 262a and 262c are provided with exhaust ports 264a and 264c at positions facing each other with the arcuate portions 261a and 261c interposed therebetween. Accordingly, when the adapter 260 in which the members 260a to 260d are combined is attached inside the chamber 11, the exhaust ports 264a and 264c are connected to the exhaust ports 74 of the lower member 72.

When the adapter 260 includes four divided members 260a to 260d as illustrated in FIG. 8B, the members 260a and 260c have the same shape, and the members 260b and 260d have the same shape.

Therefore, it is possible to standardize the members 260a and 260c and the members 260b and 260d, thereby reducing the number of members to be prepared from four to two. When actually attaching the adapter 260 to the chamber 11, for example, the adapter 260 can be configured with a combination of two members 260a and two members 260b.

In the third modification example, the adapter may include two separable members or five or more separable members. The members are not necessarily divided into equal angles, and may be, for example, a combination of two members each covering an angular range of 90° and one member covering an angular range of 180°.

According to the adapters 160 and 260 of the third modification example, the adapters 160 and 260 include a plurality of members 160a to 160c or members 260a to 260d arranged to surround the base 151 of the electrostatic chuck 15. Accordingly, it is easier to attach the adapters 160 and 260 to the chamber 11.

The adapters 160 and 260 of the third modification example have the same effects as the adapter 60 of the second modification example described above.

In the above-described embodiment and the first to third modification examples, in the plasma processing apparatuses 1 to 3 and the like, high frequency power is applied to the shower head 16 that is the upper electrode. However, the high frequency power may be applied to the electrostatic chuck 15 that is the lower electrode, or may be applied to both the upper and lower electrodes. Alternatively, the plasma processing apparatus may be an apparatus using another plasma source such as an inductively coupled plasma (ICP) apparatus.

In the above-described embodiment and the first to third modification examples, dry cleaning is performed by using the remote plasma RP. However, a plasma source used during dry cleaning is not limited thereto. For example, dry cleaning may be performed by plasma using parallel plate electrodes similar to formation of a predetermined film on the wafer 100.

In the above-described embodiment and the first to third modification examples, the plasma processing apparatuses 1 to 3 and the like are PECVD apparatuses that form a predetermined film on the wafer 100. However, the configuration of the above-described embodiment can also be applied to an etching device that etches a predetermined film that is already formed on a wafer or the like.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure.

The accompanying claims and their equivalents are intended to cover such forms or modifications as would fall within the scope and spirit of the disclosure.

What is claimed is:

1. A plasma processing system, comprising:
a processing container for processing a substrate;
an upper electrode for supplying processing gas into the processing container;
a lower electrode disposed in the processing container to face the upper electrode and on which the substrate is placed; and
a power source for supplying power to at least one of the upper electrode and the lower electrode to generate plasma in the processing container, wherein the processing container comprises:
an inclined surface that descends from an outer periphery side of the lower electrode toward a base of the lower electrode; and
an exhaust port opened on the inclined surface and exhausts air from inside the processing container.

2. The plasma processing system of claim 1, wherein the inclined surface includes a curved surface shape convex downward or flat shape in an inclination direction.

3. The plasma processing system of claim 1, wherein the inclined surface includes a curved surface shape or a flat shape in a circumferential direction.

4. The plasma processing system of claim 3, wherein the inclined surface includes a plurality of flat surfaces arranged to surround the base of the lower electrode.

5. The plasma processing system of claim 1, wherein the inclined surface is a part of a bottom wall of the processing container.

6. The plasma processing system of claim 1, wherein the inclined surface is provided on an adapter attached to a lower portion of the processing container.

7. An adapter attached to a lower portion of a processing container of a plasma processing system, wherein the plasma processing system comprises:
the processing container for processing a substrate;
an upper electrode for supplying processing gas into the processing container;
a lower electrode disposed in the processing container to face the upper electrode and on which the substrate is placed;
a power source for supplying power to at least one of the upper electrode and the lower electrode to generate plasma in the processing container; and
a pair of first exhaust ports arranged at positions facing each other with the lower electrode interposed between and configured to exhaust air from inside the processing container;
the adapter comprises:
an inclined surface that descends from an outer periphery side of the lower electrode toward a base of the lower electrode when attached to the processing container; and
a pair of second exhaust ports that are opened on the inclined surface and respectively connected to the pair of first exhaust ports.

8. The adapter of claim 7, wherein the inclined surface includes a curved surface shape convex downward or a flat shape in an inclination direction.

9. The adapter of claim 7, wherein the inclined surface includes a curved surface shape or a flat shape in a circumferential direction.

10. The adapter of claim 9, wherein the inclined surface includes a plurality of flat surfaces arranged to surround the base of the lower electrode.

11. The adapter of claim 7, wherein a plurality of members are provided to be disposable to surround the base of the lower electrode.

12. The adapter of claim 11, wherein the inclined surface is provided on each of the plurality of members.
